(19) United States
(12) Patent Application Publication
(10) Pub. No.: US 2015/0026397 A1
(43) Pub. Date: Jan. 22, 2015

(54) METHOD AND SYSTEM FOR PROVIDING MEMORY MODULE INTERCOMMUNICATION

(71) Applicant: Samsung Electronics, Ltd., Gyeonggi-do (KR)

(72) Inventor: Zhan (John) Ping, San Jose, CA (US)

(73) Assignee: Samsung Electronics, Ltd., Gyeonggi-do (KR)

(21) Appl. No.: 14/085,937

(22) Filed: Nov. 21, 2013

Related U.S. Application Data
(60) Provisional application No. 61/856,693, filed on Jul. 20, 2013.

(51) Int. Cl. G11C 7/10; G11C 14/00

(52) U.S. Cl. CPC G11C 7/1072; G11C 14/0045
USPC 711/105; 711/149

(57) ABSTRACT

Exemplary embodiments include a memory module including a plurality of connectors, at least one memory, at least one transmitter and at least one receiver. The connectors are configured to fit with a form factor of a memory socket on a server board. The memory is coupled with the connectors. The transmitter(s) are coupled with the memory. The transmitter(s) are configured to send a first plurality of signals from the memory module such that the first plurality of signals bypass the connectors. The receiver(s) are coupled with the memory. The receiver(s) are configured to receive a second plurality of signals to the memory module such that the second plurality of signals bypass the plurality of connectors.

### CROSS-REFERENCE TO RELATED APPLICATIONS

This application claims the benefit of U.S. Provisional Patent Application Ser. No. 61/856,693, filed Jul. 20, 2013, and is incorporated herein by reference.

### BACKGROUND

Modern server applications, such as data centers and server rack environments, typically use multiple server nodes that cooperate together to provide services to clients. Conventional server motherboards are typically used in such server nodes. A server motherboard includes at least a circuit board having a number of sockets configured to fit various components, one or more processors (e.g. CPUs), memory dedicated to the processors on the circuit board and an interface for performing external communication. The processors include connectors having a form factor that mates with processor sockets on the circuit board. Similarly, the memory for the processors may take the form of modules having connectors configured to fit the form factor for memory sockets on the circuit board. Typically, the memory module has a dual in line memory module (DIMM) form factor. Dynamic random access memory (DRAM) modules may thus be plugged into DIMM memory sockets on the circuit board. This memory is accessible through the CPU. Other components may also be used. Some of these may be incorporated into the circuit board or may fit dedicated socket(s) on the circuit board.

In operation, each server board performs calculations using at least its internal processors. DRAM DIMM modules including for each processor may provide faster access to items in the dedicated memory for the processors. For some applications, data may be transferred from one DIMM module to another DIMM module for the same or different CPUs. Such transfers may occur for data backups or movement of data for particular calculations. In such cases, data are routed from their locations in DIMM modules through memory controllers in the processors and to the new locations in the same or different DIMM modules. For external data transfers, the data are routed from their location in the DIMM module through the Ethernet interface and to another server board. Similarly, CPU commands, requests, and other information are routed from/to the CPU to/from the Ethernet interface. Thus, server boards may operate individually or together to provide the desired operations. However, improvement in various aspects of performance may still be advantageous.

Accordingly, a server board having improved functionality and flexibility performance is desired.

### BRIEF SUMMARY

Exemplary embodiments include a memory module including a plurality of connectors, at least one memory, at least one transmitter and at least one receiver. The connectors are configured to fit with a form factor of a memory socket on a server board. The memory is coupled with the connectors. The transmitter(s) are coupled with the memory. The transmitter(s) are configured to send a first plurality of signals from the memory module such that the first plurality of signals bypass the connectors. The receiver(s) are coupled with the memory. The receiver(s) are configured to receive a second plurality of signals to the memory module such that the second plurality of signals bypass the plurality of connectors.

According to the method and system disclosed herein, the exemplary embodiments provide a mechanism for providing additional memory having a desired type. For example, DRAM and/or flash memories having the desired ratio of DRAM to flash may be provided.

### BRIEF DESCRIPTION OF SEVERAL VIEWS OF THE DRAWINGS

FIG. 1 is a block diagram of an exemplary embodiment of a memory module.

FIG. 2 is a block diagram of an exemplary embodiment of a computer system in which the exemplary embodiment of the memory module may reside.

FIG. 3 is a block diagram of another exemplary embodiment of a memory module.

FIG. 4 is a block diagram of another exemplary embodiment of a memory module.

FIG. 5A is a block diagram of another exemplary embodiment of a computer system incorporating exemplary embodiments of memory module(s).

FIG. 5B is a side view of a block diagram of another exemplary embodiment of a computer system incorporating exemplary embodiments of memory module(s).

FIG. 6 is a side view of a block diagram of another exemplary embodiment of a computer system incorporating exemplary embodiments of memory module(s).

FIG. 7 is a side view of a block diagram of another exemplary embodiment of a computer system incorporating exemplary embodiments of memory module(s).

FIG. 8 is a side view of a block diagram of another exemplary embodiment of a computer system incorporating exemplary embodiments of memory module(s)

FIG. 9 is a side view of a block diagram of another exemplary embodiment of a computer system incorporating exemplary embodiments of memory module(s)

FIG. 10 is a flow chart depicting an exemplary embodiment of a method for providing a memory module.

FIG. 11 is a flow chart depicting an exemplary embodiment of a method for using a memory module in a computer system.

### DETAILED DESCRIPTION

The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. Further, although specific blocks are depicted, various functions of the blocks may be separated into different blocks or combined. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein. Reference is made in detail to the embodiments of the present general inventive concept, examples of which are illustrated in the accompanying drawings, wherein like reference numerals refer to the like elements throughout.

The embodiments are described below in order to explain the present general inventive concept while referring to the figures. The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified.

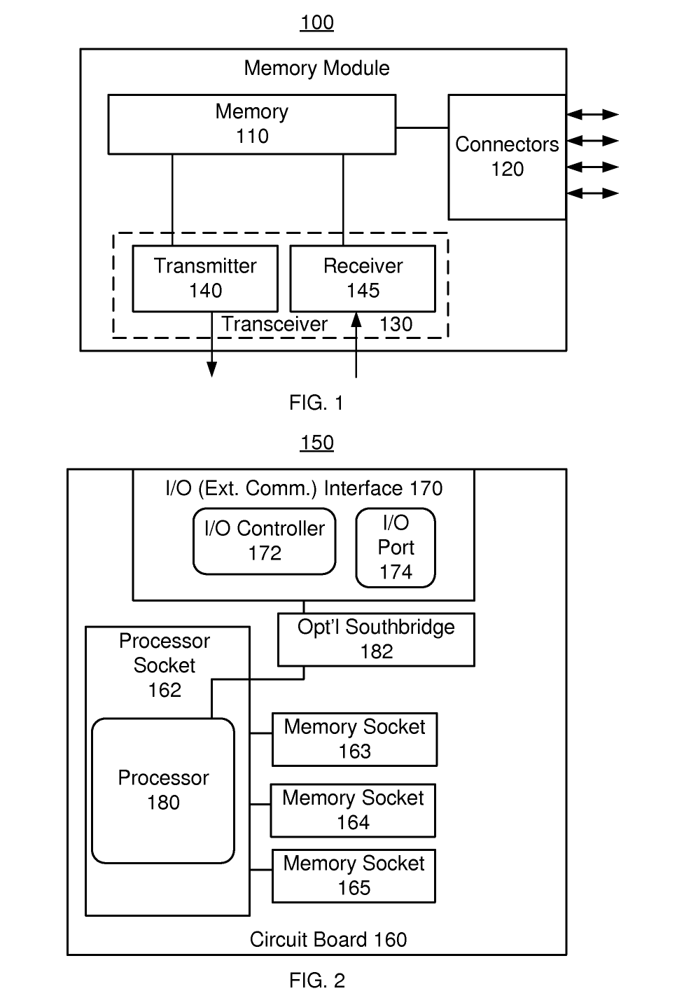

FIG. 1 is a block diagram illustrating an exemplary embodiment of a memory module 100 that make take the form of a DIMM, such as a DRAM DIMM. However, in other embodiments, the memory module 100 may take another form. FIG. 2 depicts a computer system 150 in which the memory module 100 may be employed. FIG. 2, therefore, depicts an exemplary embodiment of an environment in which the memory module 100 may operate. The computer system 150 may be a server board that may be part of a data center or other server application. In other embodiments, however, the computer system 150 may reside in another environment and/or perform other functions. Similarly, in other embodiments, the memory module 100 may reside in other devices including but not limited to a desktop, server and/or other computer environment. The computer system 100 and thus memory module 100 may reside in a rack/server environment in a server farm and/or in another computing application. Tor a server system, there may be multiple processors included on the same mother board. For simplicity, only some components are shown in FIGS. 1-2. Further, additional and/or different components may be used. For clarity, FIGS. 1-2 are not to scale.

Referring to FIGS. 1-2, the computer system 150 includes a circuit board 160 external communication interface 170, processor 180 and optional Southbridge 182. Also shown in the computer system 150 is input/output (I/O) interface 170. The I/O interface 170 may be used for external communication, for example with another server board or other computer system. The I/O interface 170 includes I/O port(s) 174 and I/O controller 172. In some embodiments, the I/O controller 172 is an Ethernet controller. In other embodiments, other controllers using other protocols for external communication may be used.

The circuit board 160 includes sockets 162, 164, 164 and 165. The circuit board 166 may also other sockets and other computing resources which are not shown for clarity. The socket 162 is a processor socket. The processor 180 may be a CPU and has pins (not shown in FIG. 2) having a form factor configured to fit the processor socket 162. The processor 180 may thus be plugged into the processor socket 162 for the computer system 160 to function as a server board. In other embodiments, multiple processors 180, processor sockets 162 and banks of memory sockets 163, 164 and 165 may be used.

The circuit board 160 also includes memory sockets 163, 164 and 165. In other embodiments, another number of memory sockets may be includes. The memory sockets 163, 164 and 165 may have a number of receptacles having a particular form factor and configured to receive connectors consistent with that form factor. For example, the memory sockets 163, 164 and 165 may be DIMM sockets and may be used for dedicated DIMM memory modules for the processor 180. Although not shown, many server boards 150 include additional sockets and computing resources. However, for simplicity, only some of the sockets and other components are depicted in FIG. 2.

The memory module 100 may be used in one or more of the sockets 163, 164 and 165 of the computer system 150. The memory module 100 includes a memory 110, connectors 120, a transmitter 140 and a receiver 145. In some embodiments, the transmitter 140 and receiver 145 functions may be performed by a single transceiver 130. In such embodiments, the transmitter 140 and receiver 145 are part of a transceiver 130. However, in other embodiments, the transmitter 140 and receiver 145 may be separated. Consequently, the transceiver 130 is depicted by a dashed line in FIG. 1. For simplicity, the term transceiver 130 is considered to include embodiments in which the transmitter 140 and receiver 145 are simply separate components.

The memory 110 may include one or more memories. For example, the memory 110 may be a DRAM, flash, magnetic random access memory (MRAM), spin transfer torque MRAM (STT-RAM) or another type of memory. The memory 110 is coupled to the connectors 120 and may be accessed via the connectors 120. Thus, the memory 110 may be accessed by and communicate with the processor 180.

The connectors 120 are configured to fit the form factor of the sockets 163, 164 and/or 165 of the computer system 150. In some embodiments, therefore, the connectors 120 are configured to fit the form factor of a DIMM slot. In such embodiments, the memory module 100 is a DIMM. The connectors 120 thus provide a mechanism for the processor 180 to access the memory 110 and other portions of the memory module 100.

The transmitter 140 and receiver 145 are used to transmit signals and receive signals between the memory modules 100 without utilizing the connectors 120. Thus, the connectors 120 may be bypassed when communication is performed through the transceiver 130. In some embodiments, a communication controller (not explicitly shown in FIG. 1) may be used to control communications via the transceiver 130. Such a communication controller may receive and schedule processor commands to be performed by the memory module 100 and control the functioning of the transmitter 140 and receiver 145. The communication controller may be part of the transceiver 130 or may be a separate component. For example, the communication controller may synchronize accesses of the memory 110 and transmission of the data by the transmitter 140 to another memory module. Similarly, the communication controller may control copying of data received from another memory module by the receiver 145 to the desired location(s) in the memory 110. The transceiver 130 may also be capable of detecting the presence of a transceiver 130 on another memory module. For example, the receiver 145 may detect a synchronization or other signal from the transmitter of another memory module. Thus, the transceiver 130 may automatically configure and manage communications with another memory module (not shown in FIGS. 1-2).

In some embodiments, the communication via the transceiver 130 is a photonic transceiver. Transmission and reception of signals by the transmitter 140 and receiver 145, respectively is accomplished using optical methods. As a result, the transmitter 140 may include a laser (not shown in FIGS. 1-2) or other optical mechanism capable of generating an optical signal. In such embodiments, the optical signals sent and received by the transmitter 140 and receiver 145 are translated to electrical signals that can be used by a remaining portion of the memory module 100. Similarly, electrical signals used by the remaining portion of the memory module 100 are translated to optical signals sent and received by the transmitter 140 and receiver 145, respectively. This translation may be performed within the transceiver 130 (or within the transmitter 140 and receiver 145) or by a separate component. In some embodiments, the transceiver 130 sends and receives optical signals wirelessly. However, in other embodiments, an optical cable may be used to connect the transceiver 130 with a transceiver on another memory module. Using the transceiver 130/transmitter 140 and receiver 145, the memory module 100 may communicate directly with another memory module that is similarly equipped. If communication is done wirelessly and photonically, then communication is done along lines of sight. However, as discussed above, optical cable(s) may be used in at least some implementations.

The memory module 100 may improve the performance of the computer system 150. In particular, transfer of data between memory modules in the memory socket(s) 163, 164 and 165 may be accomplished through the transceiver 130. Thus, the connectors 120 and processor 180 may be bypassed for such communication. Backup of data from a memory module in one socket 163, 164 or 165 to a different memory module in another socket 163, 164 or 165 may have reduced latency, consume fewer resources of the computer system 150 and allow for reduced power consumption for the data transfer than if the backup is performed through the connectors 120. Similarly, data swaps between different memory modules connected to different memory sockets 163, 164 and 165 may also be facilitated. Copying, sharing, backing up of data and similar transactions between memory modules 100 plugged into different memory sockets 163, 164 and 165 may be made possible with reduced latency and power consumption because contacts 120 and, therefore, the processor 180 are bypassed. A high bandwidth intercommunication channel between memory modules 100 coupled with the sockets 163, 164 and 165 may thus be established. Consequently, performance of the computer system 150 may be enhanced. Because these benefits are provided using the memory module 100, the architecture of the computer system 150 may remain unchanged. As a result, this improvement in performance may come without changes to the server blade environment. Thus, these improvements may be incorporated into existing computer systems by utilizing the memory module 100 in addition to or in lieu of preexisting memory modules (not shown).

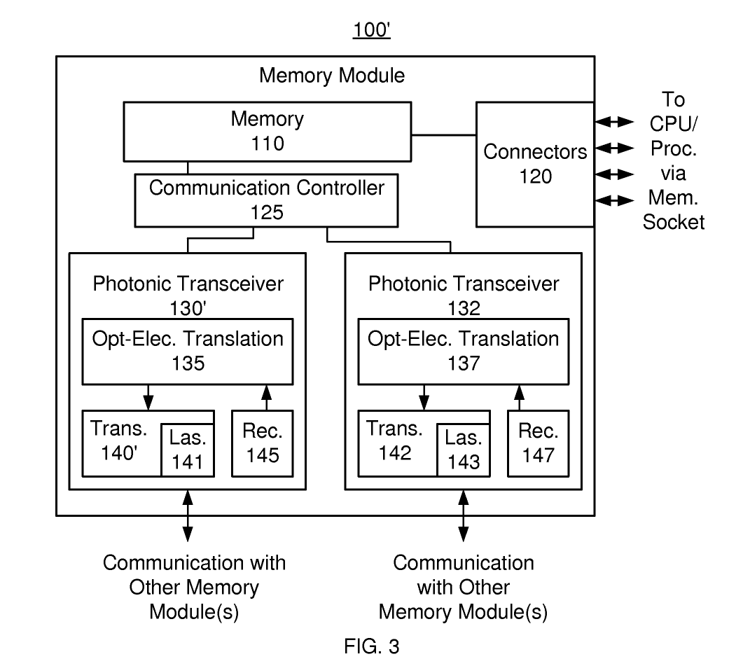

FIG. 3 is a block diagram illustrating an exemplary embodiment of a memory module 100′ that may be used in a computer system such as the computer system 150. For simplicity, only some components are shown. Further, additional and/or different components may be used. For clarity, FIG. 3 is not to scale. The memory module 100′ is analogous to the memory module 100. Analogous components in FIG. 3 are thus labeled similarly to those in FIGS. 1 and 2.

The memory module 100′ includes a memory 110, connectors 120, and a transceiver 130′ including a transmitter 140′ and a receiver 145 that are analogous to the memory 110, connectors 120, transceiver 130 including a transmitter 140 and a receiver 145, respectively. The memory module 100′ may be used in one or more of the sockets 163, 164 and 165 of the computer system 150. The memory 110 may include one or more memories. For example, the memory 110 may be a DRAM, flash, MRAM, STT-RAM or another type of memory. The memory 110 is coupled to the connectors 120 and may be accessed via the connectors 120. The connectors 120 are configured to fit the form factor of the sockets 163, 164 and/or 165 of the computer system 150. In some embodiments, therefore, the connectors 120 are configured to fit the form factor of a DIMM slot and the memory module 100′ is a DIMM. The connectors 120 thus provide a mechanism for the processor 180 to access the memory 110 on the memory module.

The transceiver 130′ is a photonic transceiver. Consequently, the transmitter 140′ includes a laser 141 and an optical-electrical signal translation block 135. The laser 141 is used for sending an optical signal. Thus, the transceiver 130′ may send and receive optical signals as well as translate between the optical signals sent/received by the transceiver 130′ and the electrical signals used to write to or read from the memory 110. The transceiver 130′ may also be capable of detecting the presence of a transceiver 130 on another memory module. For example, the receiver 145 may detect a synchronization or other signal from the transmitter of another memory module. Thus, the transceiver 130 may automatically configure and manage communications with another memory module (not shown in FIGS. 1-2).

The memory module 100′ also includes a second photonic transceiver 132. The photonic transceiver 132 is analogous to the transceiver 130. Thus, the transceiver 132 includes transmitter 142 having a laser 143, receiver 146 and optical-electrical translation block 137 that are analogous to the transceiver 130′, transmitter 140′ having laser 143 and receiver 145, respectively. The transceivers 130′ and 132 may thus be used to transmit signals from and receive signals to the memory module 100′. Thus, the connectors 120 may be bypassed when communication is performed through the transmitter 140 and/or receiver 145. Although shown as part of transceivers 130′ and 132, in other embodiments, the transmitter 140′ and 132 and the receiver 145 and 147 may be separate components. Further, two transceivers 130′ and 132 are shown in order to provide line-of-sight communication that bypasses the connectors 120 in different directions.

The memory module 100′ also includes communication controller 125. The communication controller 125 may receive and schedule processor commands to be performed by the memory module 100′ and control the functioning of the transceivers 130′ and 132. Although shown as a separate block, in other embodiments, the photonic transceiver 130′ and the photonic transceiver 132 may contain internal modules providing the functionality of the communication control 125.

Using the transceivers 130′ and 132, the memory module 100′ may improve the performance of a computer system such as the computer system 150. The benefits of the memory module 100′ may be analogous to those discussed above for the memory module 100. In addition, the transceivers 130′ and 132 may be oriented in different directions. As a result, communication may be provided to multiple different memory modules or other components with which the transceivers 130′ and 132 may be photonically connected. Consequently, performance of the computer system 150 may thus be enhanced. Because these benefits are provided using the memory module 100′, the architecture of the computer system 150 may remain unchanged. As a result, this improvement in performance may come without changes to the server blade environment. Thus, these improvements may be incorporated into existing computer systems by utilizing the memory module 100′ in addition to or in lieu of preexisting memory modules (not shown).

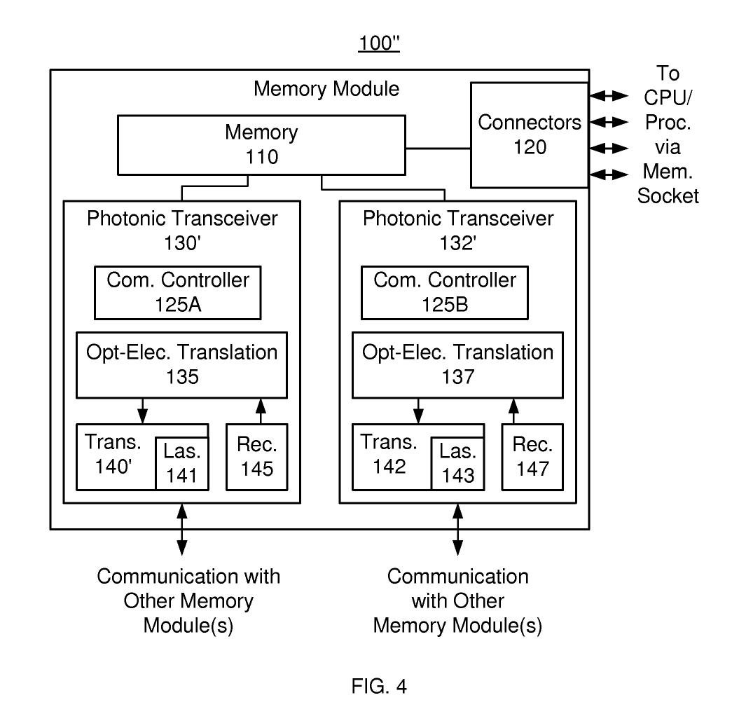

FIG. 4 is a block diagram illustrating an exemplary embodiment of a memory module 100″ that may be used in a computer system such as the computer system 150. For simplicity, only some components are shown. Further, additional and/or different components may be used. For clarity, FIG. 4 is not to scale. The memory module 100′ is analogous to the memory modules 100 and 100′. Analogous components in FIG. 4 are thus labeled similarly to those in FIGS. 1, 2 and 3.

The memory module 100″ includes a memory 110, connectors 120, a transceiver 130″ and a transceiver 132′ that are analogous to the memory 110, connectors 120, transceiver 130/130′ and transceiver 132, respectively. The memory module 100″ may be used in one or more of the sockets 163, 164 and 165 of the computer system 150. The memory 110 may include one or more memories. For example, the memory 110 may be a DRAM, flash, MRAM, STT-RAM or another type of memory. The memory 110 is coupled to the connectors 120 and may be accessed via the connectors 120. The connectors 120 are configured to fit the form factor of the sockets 163, 164 and/or 165 of the computer system 150. In some embodiments, therefore, the connectors 120 are configured to fit the form factor of a DIMM slot and the memory module 100′ is a DIMM. The connectors 120 thus provide a mechanism for the processor 180 to access the memory 110 on the memory module.

The transceivers 130″ and 132′ are photonic transceivers. Thus, the transceiver 130″ includes a transmitter 140′ having a laser 141, a receiver 145 and optical-electrical signal translation block 135 that are analogous to the transmitter 140′ having the laser 141, the receiver 145 and the optical-electrical signal translation block 135, respectively. Similarly, the transceiver 132′ includes a transmitter 142 having a laser 143, a receiver 147 and optical-electrical signal translation block 137 that are analogous to the transmitter 142 having the laser 143, the receiver 147 and the optical-electrical signal translation block 137, respectively. In addition, the communication controller functions have been moved into the transceivers 130′ and 132′ in communication controllers 125A and 125B, respectively. These communication controllers 125A and 125B are analogous to the communication controller 125 depicted in FIG. 3.

Using the transceivers 130″ and 132′, the memory module 100′ may improve the performance of a computer system such as the computer system 150. The benefits of the memory module 100′ may be analogous to those discussed above for the memory module 100. In addition, the transceivers 130′ and 132 may be oriented in different directions. As a result, communication may be provided to multiple different memory modules or other components with which the transceivers 130′ and 132 may be photonically connected. Consequently, performance of the computer system 150 may thus be enhanced. Because these benefits are provided using the memory module 100′, the architecture of the computer system 150 may remain unchanged. As a result, this improvement in performance may come without changes to the server blade environment. Thus, these improvements may be incorporated into existing computer systems by utilizing the memory module 100′ in addition to or in lieu of preexisting memory modules (not shown).

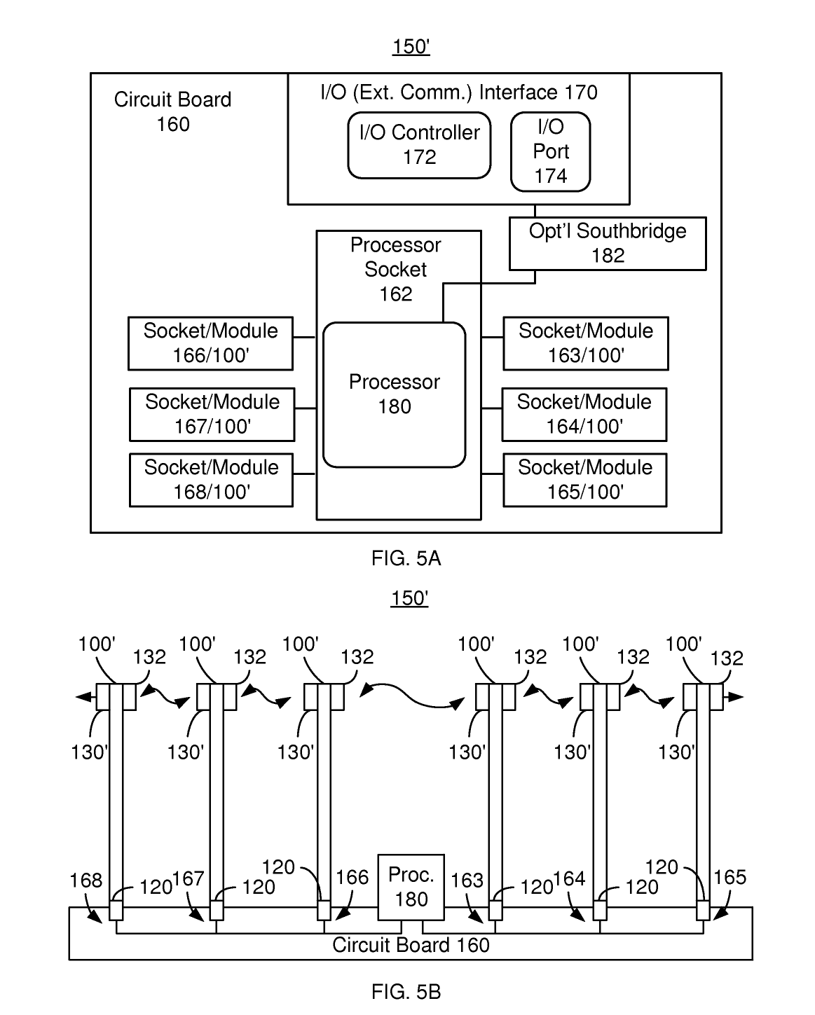

FIGS. 5A and 5B are plan and side view block diagrams illustrating an exemplary embodiment of a computer system 150′ in which a memory module may be used. For simplicity, only some components are shown. Further, additional and/or different components may be used. For clarity, FIGS. 5A and 5B are not to scale. The computer system 150′ may be a server board that may be part of a data center or other server application. Thus, in the context of FIGS. 5A-5B, the computer system 150′ is described as server board 150′. In other embodiments, however, the server board 150′ may reside in another environment and/or perform other functions. The computer system 150′ is analogous to the computer system 150. Consequently, similar components have analogous labels. The server board 150′ thus includes a circuit board 160, processor socket 162, sockets 163, 164 and 165, the I/O interface 170 having I/O controller 172 and I/O port 174, and the processor 180 that are analogous to the circuit board 160, processor socket 162, memory sockets 163, 164 and 165, the I/O interface 170 having I/O controller 172 and I/O port 174, and the processor 180, respectively, of the computer system 150. In addition, the circuit board 160 includes sockets 166, 167 and 168 that are analogous to the sockets 163, 164 and 165. Consequently, the processor 180 has access to multiple banks of memories via the sockets 163, 164 and 165 in one bank plus the sockets 166, 167 and 168 in another bank. The sockets 163, 164, 165, 166, 167 and 168 may be DIMM sockets. The sockets 163, 164, 165, 166, 167 and 168 are thus dedicated memory sockets for the processor socket 162 and the processor 180. In other embodiments, multiple processor sockets, processors, and sockets/banks of sockets may be present.

As shown in FIGS. 5A-5B, memory modules 100′ may reside in one or more of the sockets 163, 164, 165, 166, 167 and 168. In the embodiment shown, there is a memory module 100′ in each socket 163, 164, 165, 166, 167 and 168. Although the memory module 100′ is shown, in other embodiments, one or more of the memory modules 100′ may be replaced with memory modules 100, 100″ and/or analogous memory modules. Further, one or more conventional memory modules may be used.

As can be seen in FIG. 5B, the memory modules 100′ in the sockets 163, 164, 165, 166, 167 and 168 include transceivers 130′ and 132. The arrows depict communication between the transceivers 130′ and 132. In the embodiment shown, all of the memory modules 100′ intercommunicate without requiring signals to be passed through the connectors 120 or the processor 180. For example, using its transceiver 132, the memory module 100′ in socket 167 can communicate with the module 100′ in socket 166 through that module's transceiver 130′. Using its transceiver 130′, the memory module 100′ in socket 167 can communicate with the module 100′ in socket 168 through that module's transceiver 132. Because the memory module 100′ in the socket 167 can communicate with the memory modules 100′ in the sockets 166 and 168 without using the connectors 120, the memory module 100′ in the socket 166 can communicate with the memory module 100′ in the socket 168 without using the connectors 120. Intercommunication between the memory modules 100′ using transceivers 130′ and 132 can be direct (between memory modules 100′ in adjacent sockets) or indirect (between memory modules in non-adjacent sockets). Thus, exchanges of data may take place via the transceivers 130′ and 132 between memory modules that do not occupy adjacent positions. In the embodiment shown, the memory module 100′ in the socket 166 in one bank of sockets can communicate with the memory module 100′ in a socket 163 of another bank through transceivers 132 and 130′, respectively. Thus, memory modules in different memory banks may communicate while bypassing the connectors 120 and processor 180.

The computer system 150′ shares the benefits of the memory modules 100, 100′ and/or 100″ and the computer system 150. Transfer of data between memory modules 100/100′/100″ in the memory socket(s) 163, 164, 165, 166, 167 and 168 may be accomplished through the transceivers 130/130′/130″ and 132/132′. The connectors 120 and processor 180 may be bypassed for such communication. A high bandwidth intercommunication channel between memory modules 100′ coupled with the sockets 163, 164, 165, 166, 167 and 168 may thus be established. Low latency and low power communication may be made possible. Consequently, performance of the computer system 150′ may be enhanced. Because these benefits are provided using the memory modules 100/100′/100″, the architecture of the computer system 150′ may remain unchanged while these benefits are achieved.

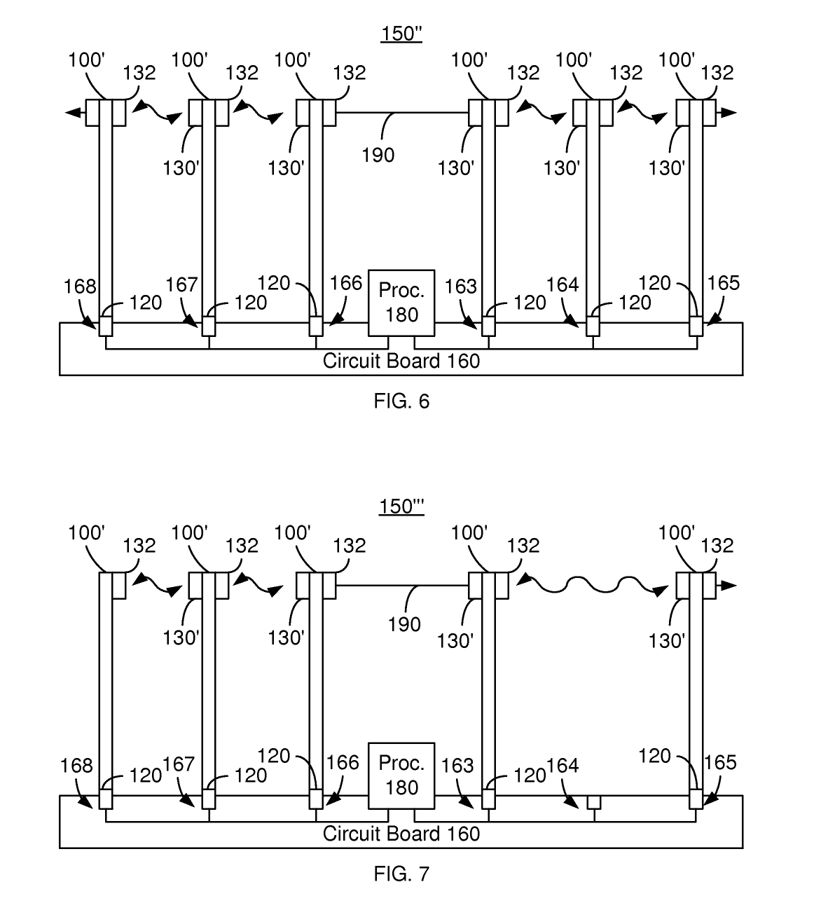

FIG. 6 is a side view block diagram illustrating an exemplary embodiment of a computer system 150″ in which a memory module may be used. For simplicity, only some components are shown. Further, additional and/or different components may be used. For clarity, FIG. 6 is not to scale. The computer system 150″ may be a server board that may be part of a data center or other server application. Thus, in the context of FIG. 6, the computer system 150″ is described as server board 150″. In other embodiments, however, the server board 150″ may reside in another environment and/or perform other functions. The computer system 150″ is analogous to the computer systems 150/150′. Consequently, similar components have analogous labels. For clarity, only some components are shown. The server board 150″ thus includes a circuit board 160, processor socket, sockets 163, 164, 165, 166, 167 and 168 and the processor 180 that are analogous to the circuit board 160, processor socket, sockets 163, 164, 165, 166, 167 and 168 and the processor 180, respectively, of the computer systems 150 and 150′. The memory modules 100′ may reside in one or more of the sockets 163, 164, 165, 166, 167 and 168. In the embodiment shown, there is a memory module 100′ in each socket 163, 164, 165, 166, 167 and 168. Although the memory module 100′ is shown, in other embodiments, one or more of the memory modules 100′ may be replaced with memory modules 100, 100″ and/or analogous memory modules. Further, one or more conventional memory modules may be used.

As can be seen in FIG. 6, the memory modules 100′ in the sockets 163, 164, 165, 166, 167 and 168 include transceivers 130′ and 132. The arrows depict communication between the transceivers 130′ and 132. In the embodiment shown, all of the memory modules 100′ intercommunicate without requiring signals to be passed through the connectors 120 or the processor 180. In addition, the memory modules 100′ in the sockets 163 and 166 are connected using an optical cable 190. Thus, photonic communication between the transceiver 132 of the module 100′ in the socket 166 and the transceiver 130′ of the module 100′ in the socket 163 is not performed wirelessly.

The computer system 150″ shares the benefits of the memory modules 100, 100′ and/or 100″ and the computer systems 150 and 150′. Transfer of data between memory modules 100/100′/100″ in the memory socket(s) 163, 164, 165, 166, 167 and 168 may be accomplished through the transceivers 130/130′/130″ and 132/132′. The connectors 120 and processor 180 may be bypassed for such communication. A high bandwidth intercommunication channel between memory modules 100′ coupled with the sockets 163, 164, 165, 166, 167 and 168 may thus be established. Low latency and low power communication may be made possible. Consequently, performance of the computer system 150″ may be enhanced. Because these benefits are provided using the memory modules 100/100′/100″, the architecture of the computer system 150″ may remain unchanged while these benefits are achieved.

FIG. 7 is a side view block diagram illustrating an exemplary embodiment of a computer system 150′″ in which a memory module may be used. For simplicity, only some components are shown. Further, additional and/or different components may be used. For clarity, FIG. 7 is not to scale. The computer system 150′″ may be a server board that may be part of a data center or other server application. Thus, in the context of FIG. 7, the computer system 150′″ is described as server board 150′″. In other embodiments, however, the server board 150′″ may reside in another environment and/or perform other functions. The computer system 150′″ is analogous to the computer systems 150/150′/150″. Consequently, similar components have analogous labels. For clarity, only some components are shown. The server board 150′″ thus includes a circuit board 160, processor socket, sockets 163, 164, 165, 166, 167 and 168, optical cable 190 and the processor 180 that are analogous to the circuit board 160, processor socket, sockets 163, 164, 165, 166, 167 and 168, optical cable 190 and the processor 180, respectively, of the computer systems 150, 150′ and 150″. The memory modules 100′ may reside in one or more of the sockets 163, 164, 165, 166, 167 and 168. In the embodiment shown, there is a memory module 100′ only in sockets 163, 165, 166, 167 and 168. Although the memory module 100′ is shown, in other embodiments, one or more of the memory modules 100′ may be replaced with memory modules 100, 100″ and/or analogous memory modules. Further, one or more conventional memory modules may be used.

The memory modules 100′ in the sockets 163, 165, 166, 167 and 168 include transceivers 130′ and 132. The arrows depict communication between the transceivers 130′ and 132. In the embodiment shown, all of the memory modules 100′ intercommunicate without requiring signals to be passed through the connectors 120 or the processor 180. This is true even though socket 164 remains unoccupied. Because they are aligned and communicate wirelessly, the transceiver 132 of the memory module 100′ in the socket 163 may still exchange data with the transceiver 130′ of the memory module 100′ in the socket 165.

The computer system 150′″ shares the benefits of the memory modules 100, 100′ and/or 100″ and the computer systems 150, 150′ and 150″. Transfer of data between memory modules 100/100′/100″ in the memory socket(s) 163, 165, 166, 167 and 168 may be accomplished through the transceivers 130/130′/130″ and 132/132′. The connectors 120 and processor 180 may be bypassed for such communication. A high bandwidth intercommunication channel between memory modules 100′ coupled with the sockets 163, 165, 166, 167 and 168 may thus be established. Low latency and low power communication may be made possible. Consequently, performance of the computer system 150′″ may be enhanced. Because these benefits are provided using the memory modules 100/100′/100″, the architecture of the computer system 150′″ may remain unchanged while these benefits are achieved.

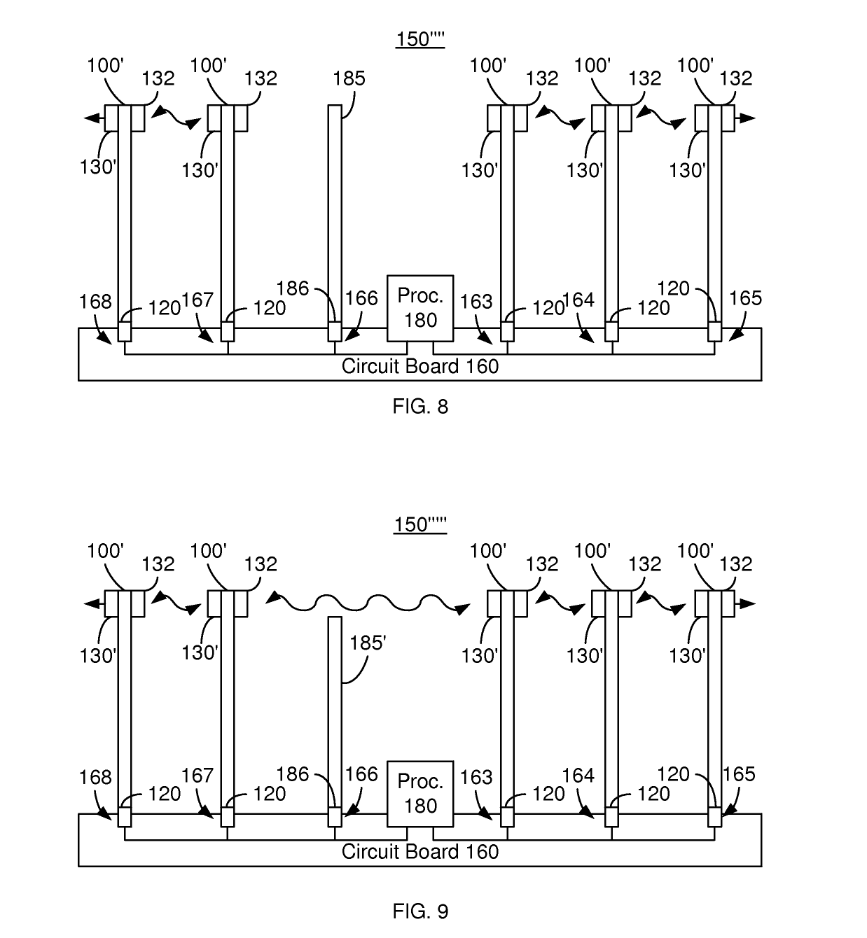

FIG. 8 is a side view block diagram illustrating an exemplary embodiment of a computer system 150″″ in which a memory module may be used. For simplicity, only some components are shown. Further, additional and/or different components may be used. For clarity, FIG. 8 is not to scale. The computer system 150″″ may be a server board that may be part of a data center or other server application. Thus, in the context of FIG. 8, the computer system 150″″ is described as server board 150″″. In other embodiments, however, the server board 150″″ may reside in another environment and/or perform other functions. The computer system 150″″ is analogous to the computer systems 150/150′/150″/150′″. Consequently, similar components have analogous labels. For clarity, only some components are shown. The server board 150″″ thus includes a circuit board 160, processor socket, sockets 163, 164, 165, 166, 167 and 168 and the processor 180 that are analogous to the circuit board 160, processor socket, sockets 163, 164, 165, 166, 167 and 168 and the processor 180, respectively, of the computer systems 150, 150′ and 150″. The memory modules 100′ may reside in one or more of the sockets 163, 164, 165, 166, 167 and 168. In the embodiment shown, there is a memory module 100′ only in sockets 163, 164, 165, 167 and 168. Although the memory module 100′ is shown, in other embodiments, one or more of the memory modules 100′ may be replaced with memory modules 100, 100″ and/or analogous memory modules. Further, a conventional memory module 185 is present. In another embodiments, another number of conventional memory modules may be used.

The memory modules 100′ in the sockets 163, 164, 165, 167 and 168 include transceivers 130′ and 132. The arrows depict communication between the transceivers 130′ and 132. In the embodiment shown, the memory modules 100′ intercommunicate without requiring signals to be passed through the connectors 120 or the processor 180. However, a memory module 185 that does not communicate using transceivers and which blocks line of sight photonic communication between socket 167 and 163 is present. Thus, the memory modules 100′ in the sockets 167 and 168 communicate with the memory modules 100′ in the sockets 163, 164 and 165 via connectors 120 and processor 180. Similarly, the memory modules 100′ in the computer system 150″″ communicate with the module 185 in socket 166 through the processor 180 and connectors 186. However, the memory modules 100′ may still be used with the memory module 185 and the computer system 150″″.

The computer system 150″″ shares the benefits of the memory modules 100, 100′ and/or 100″ and the computer systems 150, 150′, 150″ and 150′″. Transfer of data between memory modules 100/100′/100″ in the memory socket(s) 163, 164, 165, 167 and 168 may be accomplished through the transceivers 130/130′/130″ and 132/132′. The connectors 120 and processor 180 may be bypassed for such communication. A high bandwidth intercommunication channel between memory modules 100′ coupled with the sockets 163, 164 and 165 and between the memory modules 100′ coupled with the sockets 167 and 168 may thus be established. Low latency and low power communication may be made possible. Consequently, performance of the computer system 150″″ may be enhanced. However, this improvement may be somewhat attenuated because of the presence of the memory module 185. Because these benefits are provided using the memory modules 100/100′/100″, the architecture of the computer system 150″″ may remain unchanged while these benefits are achieved.

FIG. 9 is a side view block diagram illustrating an exemplary embodiment of a computer system 150′″″ in which a memory module may be used. For simplicity, only some components are shown. Further, additional and/or different components may be used. For clarity, FIG. 9 is not to scale. The computer system 150′″″ may be a server board that may be part of a data center or other server application. Thus, in the context of FIG. 9, the computer system 150′″″ is described as server board 150′″″. In other embodiments, however, the server board 150′″″ may reside in another environment and/or perform other functions. The computer system 150′″″ is analogous to the computer systems 150/150′/150″/150′″/150″″. Consequently, similar components have analogous labels. For clarity, only some components are shown. The server board 150′″″ thus includes a circuit board 160, processor socket, sockets 163, 164, 165, 166, 167 and 168 and the processor 180 that are analogous to the circuit board 160, processor socket, sockets 163, 164, 165, 166, 167 and 168 and the processor 180, respectively, of the computer systems 150, 150′, 150″ and 150′″. The memory modules 100′ may reside in one or more of the sockets 163, 164, 165, 166, 167 and 168. In the embodiment shown, there is a memory module 100′ only in sockets 163, 164, 165, 167 and 168. Although the memory module 100′ is shown, in other embodiments, one or more of the memory modules 100′ may be replaced with memory modules 100, 100″ and/or analogous memory modules. Further, a conventional memory module 185′ is present. In another embodiments, another number of conventional memory modules may be used.

The memory modules 100′ in the sockets 163, 164, 165, 167 and 168 include transceivers 130′ and 132. The arrows depict communication between the transceivers 130′ and 132. In the embodiment shown, the memory modules 100′ intercommunicate without requiring signals to be passed through the connectors 120 or the processor 180. A memory module 185′ that does not communicate using transceivers is present. However, the memory module 185′ does not block line of sight photonic communication between sockets 167 and 163. Thus, the memory modules 100′ in the sockets 167 and 163 can communicate while bypassing the connectors 120 and processor 180. Consequently, the memory modules 100′ in the sockets 163, 164, 165, 167 and 168 may communicate through transceivers 130′ and 132. In contrast, the module 185′ may only be accessed through the processor 180 and connectors 186. However, the memory modules 100′ may still be used with the memory module 185′ and the computer system 150′″″.

The computer system 150′″″ shares the benefits of the memory modules 100, 100′ and/or 100″ and the computer systems 150, 150′, 150″, 150′″ and 150″″. Transfer of data between memory modules 100/100′/100″ in the memory socket(s) 163, 164, 165, 167 and 168 may be accomplished through the transceivers 130/130′/130″ and 132/132′. The connectors 120 and processor 180 may be bypassed for such communication. A high bandwidth intercommunication channel between memory modules 100′ coupled with the sockets 163, 164, 165, 167 and 168 may thus be established. Low latency and low power communication may be made possible. Consequently, performance of the computer system 150′″″ may be enhanced. This improvement may be somewhat attenuated because of the presence of the memory module 185′. Because these benefits are provided using the memory modules 100/100′/100″, the architecture of the computer system 150′″″ may remain unchanged while these benefits are achieved.

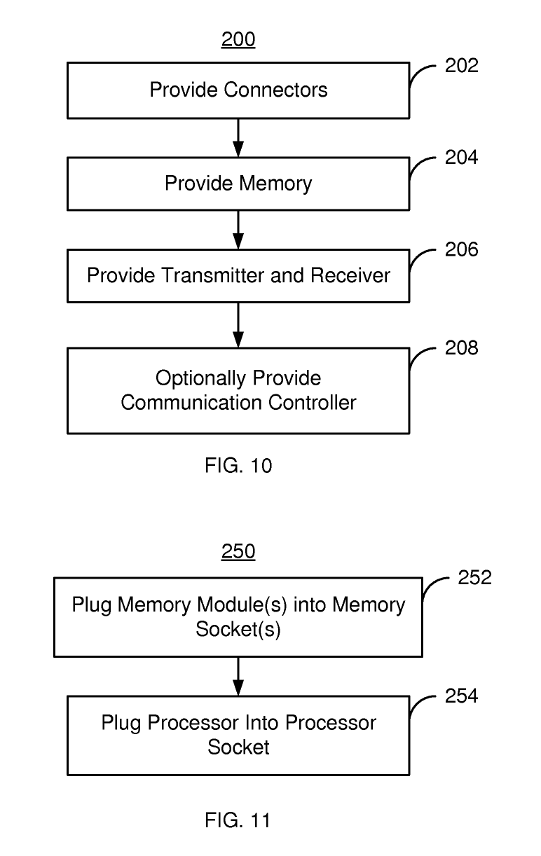

FIG. 10 is a flow chart depicting an exemplary embodiment of a method 200 for fabricating a memory module such as the memory module 100, 100 and/or, 100″. For simplicity, some steps may be omitted or combined. The method 200 is described in the context of the memory module 100′. However, the method 200 may be used for other socket interposers.

The connectors 120 are provided, via step 202. Step 202 may include configuring the connectors to have the desired form factor. For example, the connectors 120 may be configured for a memory socket such as a DIMM Socket. The memory 110 is provided, via step 204. Step 204 includes allocating an area for the memory. At least one transceiver 130 is provided in step 206. In some embodiments, step 206 includes providing separate transmitter(s) 140 and receiver(s) 145. In some embodiments, multiple transceivers may be provided in step 206. Supporting electronics such as an electrical-optical signal translator may also be provided. The communication controller 125 and/or other additional components may be provided, via step 208. Thus, the desired socket interposer may be fabricated.

Using the method 200, the memory module 100, 100′, 100″ and/or an analogous memory module may be provided. Thus, one or more of the benefits described herein may be achieved.

FIG. 9 is a flow chart depicting an exemplary embodiment of a method 250 for using a memory module such as the memory module 100, 100′ and/or 100″. For simplicity, some steps may be omitted or combined. The method 250 is described in the context of the memory module 100 and computer system 150. However, the method 250 may be used for other socket interposers and/or other computer systems.

The memory module(s) 100 are plugged into the appropriate, preexisting socket(s) 163, 164 and/or 165 of the computer system 150, via step 252. The processor 180 is also plugged into the socket 162 in the circuit board 160, via step 254. The computer system 150, or server board, may then be used with the memory module 100 in place.

Using the method 250, the memory module 100, 100′, 100″ and/or an analogous memory module may be used with the desired computer system 150, 150′, 150″, 150′″, 150″″, 150′″″ and/or analogous computer system. Thus, the computer system may enjoy better function and/or performance. For example, the latency of communication and power consumption may be reduced. As a result, performance of the computer system may be improved.

A method and system for a memory module has been disclosed. The present invention has been described in accordance with the embodiments shown, and there could be variations to the embodiments, and any variations would be within the spirit and scope of the present invention. Accordingly, many modifications may be made by one of ordinary skill in the art without departing from the spirit and scope of the appended claims.

We claim:

1. A memory module comprising:
a plurality of connectors configured to fit with a form factor of a memory socket on a server board;
at least one memory coupled with the plurality of connectors; and
a transmitter coupled with the at least one memory, the transmitter configured to send a first plurality of signals from the memory module such that the first plurality of signals bypass the plurality of connectors; and
a receiver coupled with the at least one memory, the receiver configured to receive a second plurality of signals to the memory module such that the second plurality of signals bypass the plurality of connectors.

2. The memory module of claim 1 wherein the memory socket is a dual in-line memory module (DIMM) socket and the memory module is a DIMM module.

3. The memory module of claim 1 further comprising:
a communication controller coupled with the at least one memory, the transmitter and the receiver, the communication controller for controlling communication through the transmitter and the receiver.

4. The memory module of claim 1 further comprising:
a transceiver including the transmitter and the receiver.

5. The memory module of claim 4 wherein the transceiver includes a photonic transceiver and wherein the first plurality of signals and the second plurality of signals are optical signals.

6. The memory module of claim 5 wherein the transceiver translates between the optical signals and electrical signals.

7. The memory module of claim 1 wherein the at least one memory is a dynamic random access memory.

8. A computer system comprising:
a circuit board including at least one processor socket having a processor form factor and at least one memory socket having a memory socket form factor;
at least one processor having the processor form factor and coupled with the at least one processor socket; and
at least one memory module including a plurality of connectors, at least one memory coupled with the plurality of connectors, at least one transmitter and at least one receiver, the plurality of connectors configured to fit the memory socket form factor of the at least one memory socket, the at least one transmitter being coupled with the at least one memory, the at least one transmitter configured to send a first plurality of signals from the memory module such that the first plurality of signals bypass the plurality of connectors, the at least one receiver being coupled with the at least one memory, the at least one receiver configured to receive a second plurality of: signals to the memory module such that the second plurality of signals bypass the plurality of connectors

9. The computer system of claim 8 wherein the at least one memory socket is a dual in-line memory module (DIMM) socket and the memory module is a DIMM module.

10. The computer system of claim 8 wherein the at least one memory module further includes:
a communication controller coupled with the at least one memory, the at least one transmitter and the at least one receiver, the communication controller for controlling communication through the at least one transmitter and the at least one receiver.

11. The computer system of claim 8 wherein each of the at least one memory module further includes:
at least one transceiver including the at least one transmitter and the at least one receiver.

12. The computer system of claim 11 wherein the at least one transceiver includes at least one photonic transceiver and wherein the first plurality of signals and the second plurality of signals are optical signals.

13. The computer system of claim 12 wherein the transceiver translates between the optical signals and electrical signals.

14. The computer system of claim 12 wherein the at least one memory module includes a plurality of memory modules configured such that the transceiver for one memory module of the plurality of memory modules is aligned with the transceiver of another memory module of the plurality of memory modules such that the plurality of memory modules may communicate through the plurality of optical signals.

15. The computer system of claim 8 wherein the at least one memory is a dynamic random access memory.

16. A method for providing a computer system comprising:
plugging a memory module into a memory socket of at least one memory socket of circuit board of the computer system, the circuit board also including at least one processor socket having a processor form factor, the at least one memory socket having a memory socket form factor, the memory module including a plurality of connectors, at least one memory coupled with the plurality of connectors, at least one transmitter and at least one receiver, the plurality of connectors configured to fit the memory socket form factor, the at least one transmitter being coupled with the at least one memory, the at least one transmitter configured to send a first plurality of signals from the memory module such that the first plurality of signals bypass the plurality of connectors, the at least one receiver being coupled with the at least one memory, the at least one receiver configured to receive a second plurality of signals to the memory module such that the second plurality of signals bypass the plurality of connectors; and
plugging at least one processor having the processor form factor and coupled with the at least one processor socket.

17. The method of claim 16 wherein memory socket is a dual in-line memory module (DIMM) socket and the memory module is a DIMM module.

18. The method of claim 16 wherein the memory module further includes at least one communication controller coupled with the at least one memory, the at least one transmitter and the at least one receiver, the communication controller for controlling communication through the at least one transmitter and the at least one receiver.

19. The method of claim 16 further comprising:
at least one transceiver including the at least one transmitter and the at least one receiver, wherein the at least one transceiver is at least one photonic transceiver, wherein the first plurality of signals and the second plurality of signals are optical signals and wherein the transceiver translates between the optical signals and electrical signals.
